(19) United States
(12) Patent Application Publication
(10) Pub. No.: US 2025/0176222 A1
(43) Pub. Date: May 29, 2025

(54) OXIDE SEMICONDUCTOR FILM, THIN FILM TRANSISTOR, AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Daichi SASAKI, Tokyo (JP); Emi KAWASHIMA, Tokyo (JP); Yuki TSURUMA, Tokyo (JP)

(73) Assignees: Japan Display Inc., Tokyo (JP); IDEMITSU KOSAN CO., LTD., Tokyo (JP)

(21) Appl. No.: 19/042,008

(22) Filed: Jan. 31, 2025

Related U.S. Application Data
(63) Continuation of application No. PCT/JP2023/027648, filed on Jul. 27, 2023.

(30) Foreign Application Priority Data
Aug. 25, 2022 (JP) 2022-134041

(51) Int. Cl. H10D 30/67

(52) U.S. Cl. CPC H10D 30/6755

(57) ABSTRACT

An oxide semiconductor film has a polycrystalline structure. A crystal structure of the oxide semiconductor film is a bixbyite structure. In the oxide semiconductor film, no peak intensity of a (422) plane is observed in an out-of-plane XRD diffraction pattern using Cu-Kα radiation. A crystallite diameter calculated from a peak of a (222) plane in the XRD diffraction pattern may be greater than or equal to 15 nm.

### CROSS-REFERENCE TO RELATED APPLICATIONS

This application is a Continuation of International Patent Application No. PCT/JP2023/027648, filed on Jul. 27, 2023, which claims the benefit of priority to Japanese Patent Application No. 2022-134041, filed on Aug. 25, 2022, the entire contents of each are incorporated herein by reference.

### FIELD

An embodiment of the present invention relates to an oxide semiconductor film having a polycrystalline structure (Poly-OS film). Further, an embodiment of the present invention relates to a thin film transistor including the Poly-OS film. Furthermore, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication Nos. 2021-141338, 2014-099601, 2021-153196, 2018-006730, 2016-184771, and 2021-108405). The thin film transistor including an oxide semiconductor film can be manufactured with a simple structure and low-temperature process, similar to a thin film transistor including an amorphous silicon film. Further, the thin film transistor including an oxide semiconductor film is known to have a higher field-effect mobility than the thin film transistor including an amorphous silicon film.

### SUMMARY

An oxide semiconductor film according to an embodiment of the present invention has a polycrystalline structure. A crystal structure of the oxide semiconductor film is a bixbyite structure. In the oxide semiconductor film, no peak intensity of a (422) plane is observed in an out-of-plane XRD diffraction pattern using Cu-Kα radiation.

A thin film transistor according to an embodiment of the present invention includes the oxide semiconductor film, a gate electrode provided over the oxide semiconductor film, and a gate insulating film provided between the oxide semiconductor film and the gate electrode.

An electronic device according to an embodiment of the present invention includes the thin film transistor.

### BRIEF DESCRIPTION OF DRAWINGS

FIG. 1 is a schematic cross-sectional view showing a configuration of a thin film transistor according to an embodiment of the present invention.

FIG. 2 is a schematic plan view showing a configuration of a thin film transistor according to an embodiment of the present invention.

FIG. 3 is a flowchart showing a method for manufacturing a thin film transistor according to an embodiment of the present invention.

FIG. 4 is a schematic cross-sectional view showing a method for manufacturing a thin film transistor according to an embodiment of the present invention.

FIG. 5 is a schematic cross-sectional view showing a method for manufacturing a thin film transistor according to an embodiment of the present invention.

FIG. 6 is a schematic cross-sectional view showing a method for manufacturing a thin film transistor according to an embodiment of the present invention.

FIG. 7 is a schematic cross-sectional view showing a method for manufacturing a thin film transistor according to an embodiment of the present invention.

FIG. 8 is a schematic cross-sectional view showing a method for manufacturing a thin film transistor according to an embodiment of the present invention.

FIG. 9 is a schematic cross-sectional view showing a method for manufacturing a thin film transistor according to an embodiment of the present invention.

FIG. 10 is a schematic cross-sectional view showing a method for manufacturing a thin film transistor according to an embodiment of the present invention.

FIG. 11 is a schematic diagram showing an electronic device according to an embodiment of the present invention.

FIG. 12 shows an XRD diffraction pattern of an oxide semiconductor film of Example 1.

FIG. 13 shows an XRD diffraction pattern of an oxide semiconductor film of Example 2.

FIG. 14 shows an XRD diffraction pattern of an oxide semiconductor film of Example 3-1.

FIG. 15 shows an XRD diffraction pattern of an oxide semiconductor film of Example 3-2.

FIG. 16 shows an XRD diffraction pattern of an oxide semiconductor film of Comparative Example 1.

FIG. 17 shows an XRD diffraction pattern of an oxide semiconductor film of Comparative Example 2.

### DESCRIPTION OF EMBODIMENTS

The field effect mobility of a thin film transistor including a conventional oxide semiconductor film is not so high even when a crystalline oxide semiconductor film is used in the thin film transistor. Therefore, it has been desired to improve the crystal structure of the oxide semiconductor film used in the thin film transistor and thereby improve the field effect mobility of the thin film transistor.

In view of the above problems, an embodiment of the present invention can provide an oxide semiconductor film having a novel crystal structure. Further, an embodiment of the present invention can provide a thin film transistor including the oxide semiconductor film having the novel crystal structure. Furthermore, an embodiment of the present invention can provide an electronic device including the thin film transistor.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a thin film transistor and a pixel electrode do not overlap in a plan view when expressed as “a pixel electrode over a thin film transistor.” On the other hand, the expression “a pixel electrode vertically over a thin film transistor” means a positional relationship in which the thin film transistor and the pixel electrode overlap in a plan view. In addition, a plan view refers to viewing from a direction perpendicular to a surface of the substrate.

In the present specification and the like, the terms “film” and “layer” can be optionally interchanged with one another.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “α includes A, B, or C,” “α includes any of A, B, or C,” or “α includes one selected from a group consisting of A, B and C,” and the like does not exclude the case where α includes a plurality of combinations of A to C unless otherwise specified. Further, these expressions do not exclude the case where a includes other components.

In addition, the following embodiments can be combined with each other as long as there is no technical contradiction.

### First Embodiment

An oxide semiconductor film according to an embodiment of the present invention is described.

### 1. Composition of Oxide Semiconductor Film

The oxide semiconductor film according to the present embodiment contains indium (In) and at least one or more metal elements (M) other than indium. That is, the metal elements other than indium contained in the oxide semiconductor film may be one type of metal element or may be a plurality of types of metal elements. It is preferable that the composition ratio of the oxide semiconductor film has an atomic ratio of indium and at least one or more metal elements which satisfies Formula (1). In other words, it is preferable that the ratio of indium to all metal elements in the oxide semiconductor film is greater than or equal to 50%. When the ratio of indium in the oxide semiconductor film increases, the oxide semiconductor film having crystallinity can be formed. Further, it is preferable that a crystal structure of the oxide semiconductor film has a bixbyite structure. When the ratio of indium in the oxide semiconductor film increases, the oxide semiconductor film having a bixbyite structure can be formed.

$$0.01 < \frac{[ M ]}{[ In ] + [ M ]} < 0.5 \qquad ( 1 )$$

Although the details of a method for manufacturing the oxide semiconductor film are described later together with a method for manufacturing a thin film transistor, the oxide semiconductor film can be formed by a sputtering method. The composition of the oxide semiconductor film formed by the sputtering method depends on the composition of the sputtering target. When the sputtering target has the above-described composition, the oxide semiconductor film without composition deviation of the metal elements can be formed by the sputtering method. Therefore, the composition of the metal element (indium and other metal elements) in the oxide semiconductor film may be equivalent to the composition of the metal element in the sputtering target. For example, the composition of the metal elements in the oxide semiconductor film can be specified based on the composition of the metal elements in the sputtering target. In addition, oxygen contained in the oxide semiconductor film is not limited thereto because it changes depending on the process conditions of the sputtering method.

Further, the composition of the metal elements in the oxide semiconductor film can be specified by X-ray fluorescence analysis, electron probe micro analyzer (EPMA) analysis, or the like. Since the oxide semiconductor film has a polycrystalline structure, the composition of the oxide semiconductor film may be specified by X-ray diffraction (XRD). Specifically, the composition of the metal elements in the oxide semiconductor film can be specified based on the crystal structure and lattice constant of the oxide semiconductor film obtained by XRD.

### 2. Crystal Structure of Oxide Semiconductor Film

The oxide semiconductor film according to the present embodiment has a polycrystalline structure including a plurality of crystal grains. Although the details of the method for manufacturing the oxide semiconductor film are described later, the oxide semiconductor film having a novel polycrystalline structure different from a conventional oxide semiconductor film can be formed using a polycrystalline oxide semiconductor (Poly-OS) technique. Therefore, hereinafter, the oxide semiconductor film having a polycrystalline structure according to the present embodiment may be referred to as a Poly-OS film in order to distinguish it from the conventional oxide semiconductor film having a polycrystalline structure.

Although the crystal structure of the Poly-OS film is not limited to a certain structure, it is preferable that the Poly-OS film has a bixbyite structure. The crystal structure of the Poly-OS film can be specified by an XRD method or an electron beam diffraction method.

The crystal structure of the Poly-OS film is different from that of the conventional oxide semiconductor film having a polycrystalline structure. Specifically, the present inventors have found that although the Poly-OS film has a polycrystalline structure, the polycrystalline structure of the Poly-OS film is different from that of a conventional oxide semiconductor film. That is, the present inventors have completed an oxide semiconductor film having a novel polycrystalline structure (Poly-OS film) different from that of the conventional oxide semiconductor film as a result of various trials and errors.

There are two types of XRD measurement, an out-of-plane measurement and an in-plane measurement. The out-of-plane measurement can evaluate a lattice plane parallel to a surface of a film, and the in-plane measurement can evaluate a lattice plane perpendicular to a surface of a film. The characteristics of the Poly-OS film can be obtained in the out-of-plane measurement.

Here, the crystal plane (001) of the bixbyite structure in the present specification includes (001) and its equivalents (100) and (010). Similarly, the crystal plane (101) includes (101) and its equivalents (110) and (011). Further, the crystal plane (111) represents (111). Furthermore, in each plane, “1” may be “−1” and is considered to be an equivalent plane to each plane.

In addition, crystal planes include (hk0) (h≠k, h and k are natural numbers), (hhl) (h≠l, h and l are natural numbers), and (hkl) (h≠k≠l, h, k, and l are natural numbers) other than (001), (101), and (111).

### 2-1. Peak Intensity

When an oxide semiconductor film has crystallinity, a peak appears at a certain diffraction angle in an XRD diffraction pattern obtained by an out-of-plane measurement. For example, a conventional crystalline oxide semiconductor film containing indium whose ratio is greater than or equal to 50% and having a bixbyite structure has peaks at diffraction angles (2θ) near 31 degrees and near 44 degrees in an XRD diffraction pattern. The peak at the diffraction angle near 31 degrees is attributed to a (222) plane of the bixbyite structure. The peak at the diffraction angle near 44 degrees is attributed to a (422) plane of the bixbyite structure. Further, the peak intensity at the diffraction angle near 31 degrees is significantly greater than the peak intensity at the diffraction angle near 44 degrees. This means that many crystals having the (222) plane exists in a direction parallel to the surface of the oxide semiconductor film.

In addition, the diffraction angle of the XRD diffraction pattern of the oxide semiconductor film may change depending on the composition of metal elements contained in the oxide semiconductor film or the manufacturing conditions of the oxide semiconductor film. Therefore, in the present specification, “near” an angle of a diffraction angle peak is defined to include a range of ±2 degrees of the diffraction angle of the peak.

An XRD diffraction pattern of the Poly-OS film having a bixbyite structure also has a peak at the diffraction angle near 31 degrees, which corresponds to the (222) plane of the bixbyite structure. However, the peak intensity of the diffraction angle near 31 degrees of the Poly-OS film is smaller than the peak intensity of the diffraction angle near 31 degrees of a conventional crystalline oxide semiconductor film with the same film thickness. For example, the peak intensity of the diffraction angle near 31 degrees of the Poly-OS film is less than half the peak intensity of the diffraction angle near 31 degrees of the conventional crystalline oxide semiconductor film with the same film thickness.

In the XRD diffraction pattern of the Poly-OS film, a peak may appear at the diffraction angle near 44 degrees. When a peak appears at the diffraction angle near 44 degrees, a ratio of the peak intensity at the diffraction angle near 31 degrees to the peak intensity at the diffraction angle near 44 degrees (hereinafter, referred to as a “peak intensity ratio”) is less than or equal to 3.0. Further, in the XRD diffraction pattern of the Poly-OS film, a peak may not appear at the diffraction angle near 44 degrees. Furthermore, in the XRD diffraction pattern of the Poly-OS film, a peak may appear at a diffraction angle near 52 degrees corresponding to a (440) plane of the bixbyite structure. These phenomena indicate that the Poly-OS film has few crystals having the (222) plane in the direction parallel to the surface of the Poly-OS film, and the orientation is relaxed. As a result, a state appears in which many crystals have the (440) plane in the direction parallel to the surface of the Poly-OS film, and the Poly-OS film has a unique crystal arrangement different from the conventional crystalline oxide semiconductor film.

As described above, the Poly-OS film shows a characteristic XRD diffraction pattern different from that of the conventional crystalline oxide semiconductor film. Specifically, when the Poly-OS film has a bixbyite structure, a peak intensity of the (222) plane in the XRD diffraction pattern is small. When a peak of the (422) plane appears, the peak intensity ratio of the (222) plane to the (422) plane is less than or equal to 3.0, and preferably less than or equal to 2.0. Further, the peak intensity is generally small in the Poly-OS film, and a peak of the (422) plane may not appear. Furthermore, a peak of the (440) plane may appear in the Poly-OS film, which means that the orientation of the (222) plane with respect to the surface of the Poly-OS film is relaxed and the (440) plane is arranged in the direction parallel to the surface of the Poly-OS film. In other words, the crystals included in the Poly-OS film have a characteristic crystal arrangement different from that of conventional crystals.

### 2-2. Crystallite Size

A crystal grain in the Poly-OS film may include a plurality of crystallites. A crystallite diameter D can be calculated by the Scherrer formula shown in

$$D = K λ / β cos θ \qquad ( 2 )$$

Formula (2) using a peak width of the XRD diffraction pattern. Here, K is the Scherrer constant, λ is the wavelength of the X-ray, β is the half-width of the peak, and θ is the Bragg angle (corresponding to ½ of the diffraction angle 2θ).

In the case of the Poly-OS film having a bixbyite structure, the crystallite diameter D of crystal grains contained in the Poly-OS film can be calculated using the half-width of the peak corresponding to the (222) plane. In the out-of-plane XRD diffraction pattern using Cu-Kα radiation, the crystallite diameter D is greater than or equal to 10 nm, preferably greater than or equal to 15 nm, and more preferably greater than or equal to 20 nm. When the thickness of the Poly-OS film is less than or equal to 20 nm, the crystallite diameter D is preferably 0.95 times greater than or equal to the thickness d of the Poly-OS film. That is, the crystallite diameter D is preferably approximately equal to the thickness of the Poly-OS film. In addition, when the thickness of the Poly-OS film is small, the crystallite diameter D may exceed the thickness of the Poly-OS film. In this case, when the crystallite diameter D is a value close to the thickness of the Poly-OS film, it means that the crystallite diameter D is almost equal to the thickness of the Poly-OS film, and can be determined to be 0.95 times greater than or equal to the thickness d of the Poly-OS film.

As described above, the peak intensity of the (222) plane in the XRD diffraction pattern of the Poly-OS film is small. However, the crystallite diameter of the Poly-OS film is similar to that of the conventional crystalline oxide semiconductor film. Therefore, the Poly-OS film has a novel crystal structure in which the crystal orientation is more relaxed than that of the conventional crystalline oxide semiconductor film, and the long-range atomic order is maintained in the thickness direction (the direction perpendicular to the film surface).

As described above, the oxide semiconductor film according to an embodiment of the present invention, that is, the Poly-OS film, has a novel crystal structure. Although the details are described later, when the Poly-OS film having such a novel crystal structure is used as a channel of a thin film transistor, the field effect mobility is not reduced but is actually improved. Therefore, the thin film transistor including the Poly-OS film has improved electrical characteristics.

### Second Embodiment

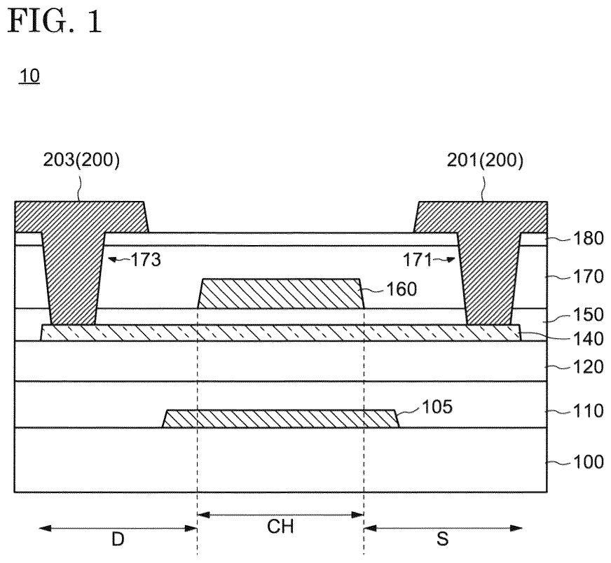

A thin film transistor 10 according to an embodiment of the present invention is described with reference to FIGS. 1 to 10. For example, the thin film transistor 10 may be used in an integrated circuit (IC) such as a micro-processing unit (MPU) or a memory circuit in addition to a transistor used in a display device.

### 1. Configuration of Thin Film Transistor 10

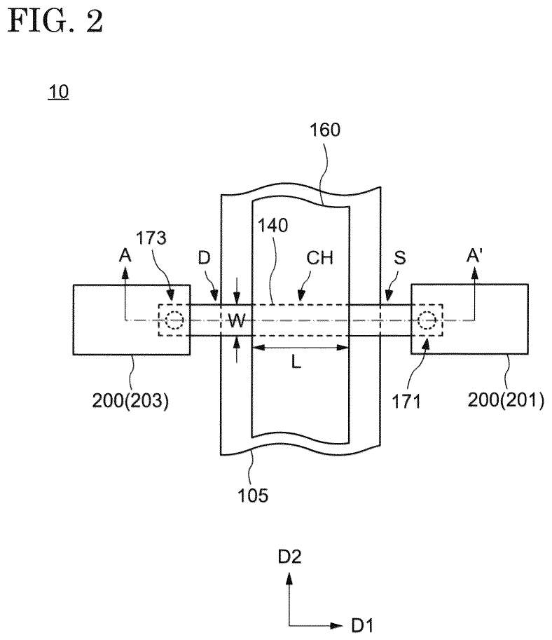

A configuration of a thin film transistor 10 according to an embodiment of the present invention is described with reference to FIGS. 1 and 2. FIG. 1 is a schematic cross-sectional view showing the configuration of the thin film transistor 10 according to an embodiment of the present invention. FIG. 2 is a schematic plan view showing the configuration of the thin film transistor 10 according to an embodiment of the present invention. Specifically, FIG. 1 is a cross-sectional view cut along the line A-A′ in FIG. 2.

As shown in FIG. 1, the thin film transistor 10 includes a substrate 100, a light shielding layer 105, a first insulating layer 110, a second insulating layer 120, an oxide semiconductor layer 140, a gate insulating layer 150, a gate electrode 160, a third insulating layer 170, a fourth insulating layer 180, a source electrode 201, and a drain electrode 203. The light shielding layer 105 is provided on the substrate 100. The first insulating layer 110 is provided on the substrate 100 so as to cover an upper surface and an edge surface of the light shielding layer 105. The second insulating layer 120 is provided on the first insulating layer 110. The oxide semiconductor layer 140 is provided on the second insulating layer 120. The gate insulating layer 150 is provided on the second insulating layer 120 so as to cover an upper surface and an edge surface of the oxide semiconductor layer 140. The gate electrode 160 is provided on the gate insulating layer 150 so as to overlap the oxide semiconductor layer 140. The third insulating layer 170 is provided on the gate insulating layer 150 so as to cover an upper surface and an edge surface of the gate electrode 160. The fourth insulating layer 180 is provided on the third insulating layer 170. The gate insulating layer 150, the third insulating layer 170, and the fourth insulating layer 180 are provided with opening portions 171 and 173 through which a part of the upper surface of the oxide semiconductor layer 140 is exposed. The source electrode 201 is provided on the fourth insulating layer 180 and inside the opening portion 171, and is in contact with the oxide semiconductor layer 140. Similarly, the drain electrode 203 is provided on the fourth insulating layer 180 and inside the opening portion 173, and is in contact with the oxide semiconductor layer 140. In the following description, when the source electrode 201 and the drain electrode 203 are not particularly distinguished from each other, they may be collectively referred to as a source-drain electrode 200.

The oxide semiconductor layer 140 is divided into a source region S, a drain region D, and a channel region CH based on the gate electrode 160. That is, the oxide semiconductor layer includes the channel region CH which overlaps the gate electrode 160 and the source region S and the drain region D which do not overlap the gate electrode 160. In a thickness direction of the oxide semiconductor layer 140, an edge portion of the channel region CH is substantially aligned with an edge portion of the gate electrode 160. The channel region CH has properties of a semiconductor. Each of the source region S and the drain region D has properties of a conductor. Therefore, the electrical conductivities of the source region S and the drain region D are larger than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 2, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the thin film transistor 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105. Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The first insulating layer 110, the second insulating layer 120, the third insulating layer 170, and the fourth insulating layer 180 can prevent impurities from diffusing into the oxide semiconductor layer 140. Specifically, the first insulating layer 110 and the second insulating layer 120 can prevent diffusion of impurities contained in the substrate 100, and the third insulating layer 170 and the fourth insulating layer 180 can prevent diffusion of impurities (for example, water) entering from the outside. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for each of the first insulating layer 110, the second insulating layer 120, the third insulating layer 170, and the fourth insulating layer 180. Here, silicon oxynitride (SiOₓN_{y}) and aluminum oxynitride (AlOₓN_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, each of the first insulating layer 110, the second insulating layer 120, the third insulating layer 170, and the fourth insulating layer 180 may have a single layer structure or a laminated structure.

Further, each of the first insulating layer 110, the second insulating layer 120, the third insulating layer 170, and the fourth insulating layer 180 may have a planarization function or a function of releasing oxygen by a heat treatment. However, when the second insulating layer 120 includes a silicon oxide film or a silicon oxynitride film, it is preferable that a hydrogen concentration of the silicon oxide film or the silicon oxynitride film is reduced. For example, the hydrogen concentration of the silicon oxide film used in the second insulating layer 120 is smaller than the hydrogen concentration of the silicon oxide film used in the third insulating layer 170.

The silicon oxide film or silicon oxynitride film included in the second insulating layer 120 may or may not be in contact with the oxide semiconductor layer 140. When the silicon oxide film and the oxide semiconductor layer 140 are not in contact with each other, it is preferable that another oxide insulating film is provided between the silicon oxide film and the oxide semiconductor layer 140. For example, a metal oxide containing one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid elements is used for the oxide insulating film. In particular, it is preferable to use a metal oxide containing aluminum (e.g., aluminum oxide, etc.) as the metal oxide. The metal oxide containing aluminum has high barrier properties against gases such as hydrogen or water.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, source electrode 201, and drain electrode 203 may have a single layer structure or a laminated structure.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AlOₓN_{y}), or the like is used for the gate insulating layer 150. The gate insulating layer 150 preferably has a composition close to the stoichiometric ratio. Further, the gate insulating layer 150 preferably has few defects. For example, an oxide in which few defects are observed when evaluated by electron spin resonance (ESR) may be used for the gate insulating layer 150.

The Poly-OS film described in the First Embodiment can be used as the oxide semiconductor layer 140.

Although the configuration of the thin film transistor 10 is described above, the thin film transistor 10 described above is a so-called top-gate transistor. The thin film transistor 10 can be modified in various ways. For example, when the light shielding layer 105 has conductivity, the thin film transistor 10 may have a structure in which the light shielding layer 105 functions as a gate electrode, and the first insulating layer 110 and the second insulating layer 120 function as gate insulating layers. In this case, the thin film transistor 10 is a so-called dual-gate transistor. Further, when the light shielding layer 105 has conductivity, the light shielding layer 105 may be a floating electrode and may be connected to the source electrode 201. Furthermore, the thin film transistor 10 may be a so-called bottom-gate transistor in which the light shielding layer 105 functions as a main gate electrode.

### 2. Method for Manufacturing Thin Film Transistor 10

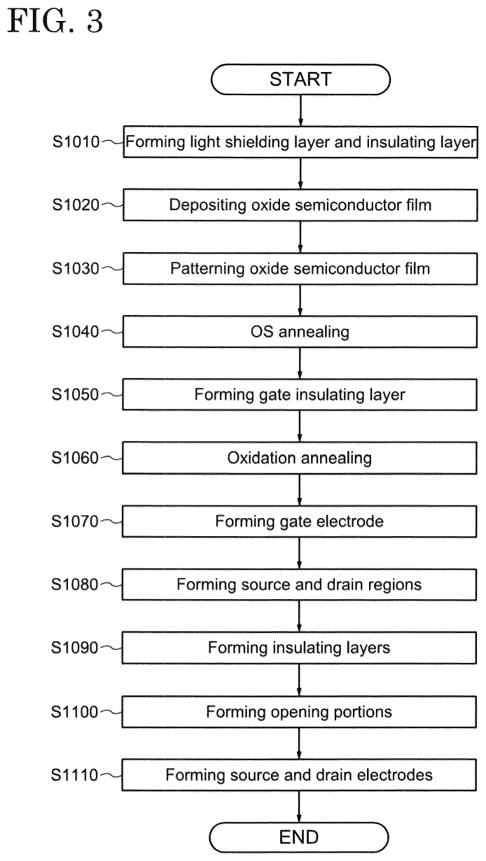

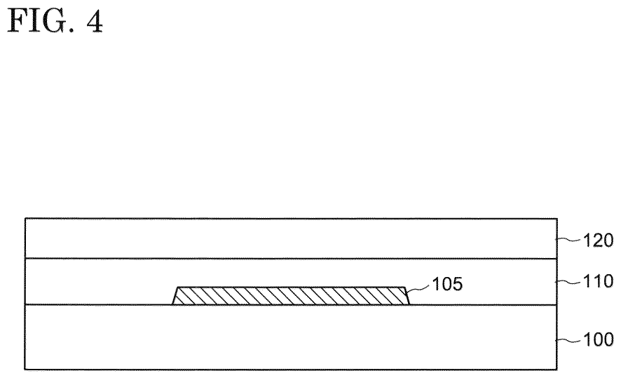

A method for manufacturing the thin film transistor 10 according to an embodiment of the present invention is described with reference to FIGS. 3 to 10. FIG. 3 is a flowchart showing the method for manufacturing the thin film transistor 10 according to an embodiment of the present invention. FIGS. 4 to 10 are schematic cross-sectional views showing the method of manufacturing the thin film transistor 10 according to an embodiment of the present invention.

As shown in FIG. 3, the method for manufacturing the thin film transistor 10 includes steps S1010 to S1110. In the following description, although the steps S1010 to S1110 are described in order, the order of the steps may be interchanged in the method for manufacturing the thin film transistor 10. Further, the method for manufacturing the thin film transistor 10 may include additional steps.

In the step S1010, the light shielding layer 105 having a predetermined pattern is formed on the substrate 100. The patterning of the light shielding layer 105 is performed using a photolithography method. The first insulating layer 110 and the second insulating layer 120 are formed on the light shielding layer 105 (see FIG. 4). The first insulating layer 110 and the second insulating layer 120 are deposited using a CVD method. For example, a silicon nitride film and a silicon oxide film are deposited as the first insulating layer 110 and the second insulating layer 120, respectively. When the silicon nitride film is used as the first insulating layer 110, the first insulating layer 110 can block impurities that diffuse from the substrate 100 into the oxide semiconductor layer 140. When the silicon oxide film is used as the second insulating layer 120, the second insulating layer 120 can release oxygen by a heat treatment.

Further, the silicon oxide film used as the second insulating layer 120 is deposited by adjusting the gas flow rate ratio so as to reduce the hydrogen concentration. When the silicon oxide film is deposited using monosilane (SiH₄) gas and dinitrogen monoxide (N₂O) gas, the gas flow rate ratio of monosilane gas to dinitrogen monoxide gas is SiH₄:N₂O=1:50 to 200 (less than or equal to 50 and less than or equal to 200), for example.

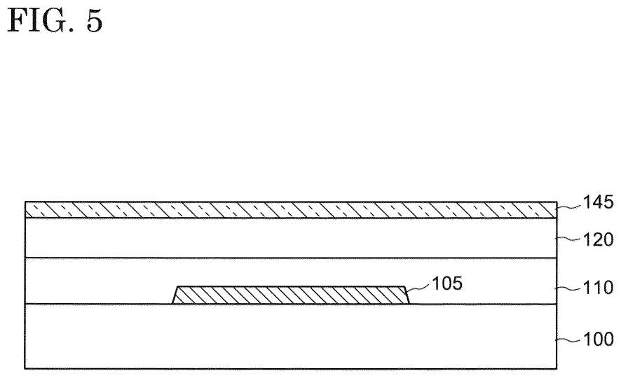

In the step S1020, an oxide semiconductor film 145 is deposited on the second insulating layer 120 (see FIG. 5). The oxide semiconductor film 145 is deposited by a sputtering method. The thickness of the oxide semiconductor film 145 is, for example, greater than or equal to 10 nm and less than or equal to 100 nm, preferably greater than or equal to 15 nm and less than or equal to 70 nm, and more preferably greater than or equal to 15 nm and less than or equal to 40 nm.

The oxide semiconductor film 145 in the step S1020 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is deposited by a sputtering method, the oxide semiconductor film 145 is deposited while controlling the temperature of the object to be deposited (the substrate 100 and the layers deposited on the substrate 100) to less than or equal to 100° C., preferably less than or equal to 80° C., and more preferably less than or equal to 50° C. The oxygen partial pressure is greater than or equal to 2% and less than or equal to 20%, preferably greater than or equal to 3% and less than or equal to 15%, and more preferably greater than or equal to 3% and less than 10%.

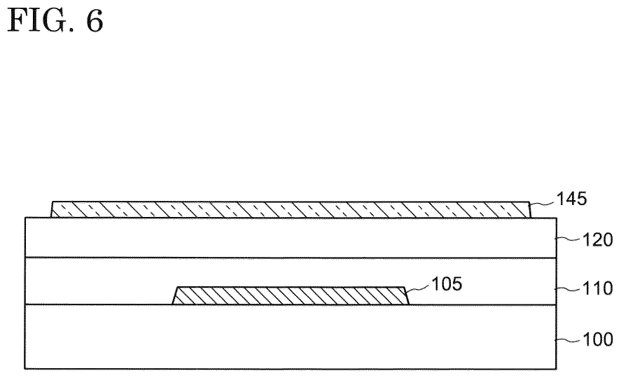

In the step S1030, the oxide semiconductor film 145 is patterned (see FIG. 6). The patterning of the oxide semiconductor film 145 is performed using a photolithography method. Wet etching or dry etching may be used for the etching of the oxide semiconductor film 145. Wet etching can be performed using an acidic etchant. For example, oxalic acid, PAN, sulfuric acid, a hydrogen peroxide solution, hydrofluoric acid, or the like can be used for the etchant.

In the step S1040, a heat treatment is performed on the oxide semiconductor film 145. Hereinafter, the heat treatment performed in step S1040 is referred to as “OS annealing.” In the OS annealing, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. The holding time at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure (that is, the oxide semiconductor including the Poly-OS) by the OS annealing.

Although hydrogen or water contained in the oxide semiconductor layer 140 is removed in the OS annealing, hydrogen or water contained in the second insulating layer 120 may also be removed through the oxide semiconductor layer 140. Hydrogen or water diffusing from the second insulating layer 120 to the oxide semiconductor layer 140 may be an inhibitor or promoter of crystallization. When such a crystallization factor is used for crystallization, a conventional crystalline oxide semiconductor layer is formed. Therefore, in the present embodiment, the hydrogen concentration of the silicon oxide film contained in the second insulating layer 120 is reduced in step S1010 in order to eliminate the above-described crystallization factor. As a result, the diffusion of hydrogen or water from the second insulating layer 120 to the oxide semiconductor layer 140 is suppressed in the OS annealing, and the Poly-OS film having a novel crystal structure different from the conventional oxide semiconductor layer can be formed.

In addition, it is preferable that an aluminum oxide film is formed over the silicon oxide film as the second insulating layer 120 in step S1010. Since the aluminum oxide film can block hydrogen or water from the silicon oxide film, the diffusion of hydrogen or water from the second insulating layer 120 to the oxide semiconductor layer 140 is further suppressed in OS annealing.

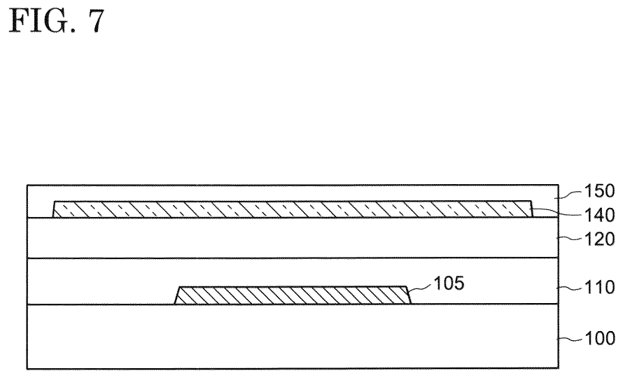

In the step S1050, the gate insulating layer 150 is formed on the oxide semiconductor layer 140 (see FIG. 7). The gate insulating layer 150 is deposited using a CVD method. For example, silicon oxide is deposited for the gate insulating layer 150. In order to reduce defects in the gate insulating layer 150, the gate insulating layer 150 may be deposited at a deposition temperature higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm. After the gate insulating layer 150 is deposited, a treatment for introducing oxygen into a part of the gate insulating layer 150 may be performed.

In the step S1060, a heat treatment is performed on the oxide semiconductor layer 140. Hereinafter, the heat treatment performed in step S1060 is referred to as “oxidation annealing.” When the gate insulating layer 150 is formed on the oxide semiconductor layer 140, many oxygen vacancies are generated on the top surface and side surfaces of the oxide semiconductor layer 140. When oxidation annealing is performed, oxygen is supplied from the second insulating layer 120 and the gate insulating layer 150 to the oxide semiconductor layer 140, and oxygen deficiencies are repaired.

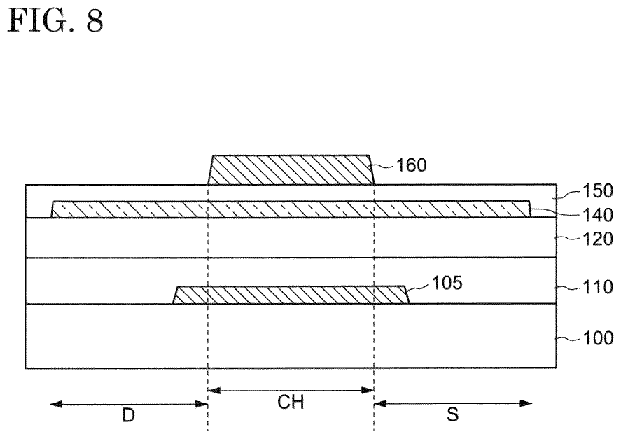

In the step S1070, the gate electrode 160 having a predetermined pattern is formed on the gate insulating layer 150 (see FIG. 8). The gate electrode 160 is deposited by a sputtering method or an atomic layer deposition method, and patterning of the gate electrode 160 is performed using a photolithography method.

In the step S1080, the source region S and the drain region D are formed in the oxide semiconductor layer 140 (see FIG. 8). The source region S and the drain region D are formed by ion implantation. Specifically, impurities are implanted into the oxide semiconductor layer 140 through the gate insulating layer 150 using the gate electrode 160 as a mask. For example, argon (Ar), phosphorus (P), boron (B), or the like is used as the implanted impurity. Oxygen deficiencies are generated by the ion implantation in the source region S and the drain region D that do not overlap the gate electrode 160, and hydrogen is trapped in the generated oxygen deficiencies. In this way, the resistance of the source region S and the drain region D is lowered. On the other hand, since no impurities are implanted in the channel region CH that overlaps the gate electrode 160, the resistance of the channel region CH is not lowered.

In addition, in the thin film transistor 10, since impurities are implanted into the oxide semiconductor layer 140 through the gate insulating layer 150, impurities such as argon (Ar), phosphorus (P), boron (B), or the like are included in the gate insulating layer 150.

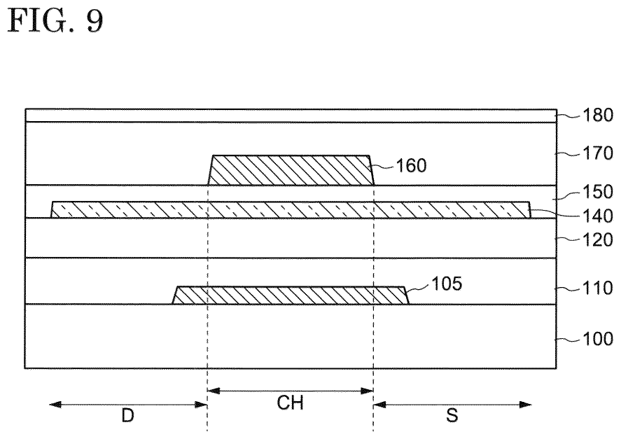

In the step S1090, the third insulating layer 170 and the fourth insulating layer 180 are formed over the gate insulating layer 150 and the gate electrode 160 (see FIG. 9). The third insulating layer 170 and the fourth insulating layer 180 are deposited using a CVD method. For example, silicon oxide and silicon nitride are deposited for the third insulating layer 170 and the fourth insulating layer 180, respectively. The thickness of the third insulating layer 170 is greater than or equal to 50 nm and less than or equal to 500 nm. The thickness of the fourth insulating layer 180 is also greater than or equal to 50 nm and less than or equal to 500 nm.

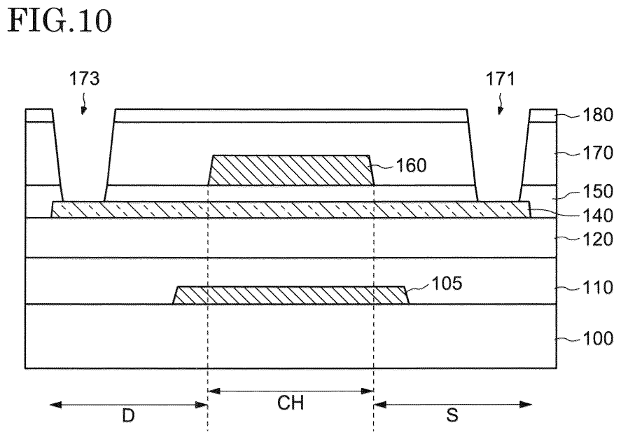

In the step S1100, the opening portions 171 and 173 are formed in the gate insulating layer 150, the third insulating layer 170, and the fourth insulating layer 180 (see FIG. 10). The source region S and the drain region D of the oxide semiconductor layer 140 are exposed by the formation of the opening portions 171 and 173.

In the step S1110, the source electrode 201 is formed on the fourth insulating layer 180 and inside the opening portion 171, and the drain electrode 203 is formed on the fourth insulating layer 180 and inside the opening portion 173. The source electrode 201 and the drain electrode 203 are formed as the same layer. Specifically, the source electrode 201 and the drain electrode 203 are formed by patterning one deposited conductive film. The thin film transistor 10 shown in FIG. 1 is manufactured through the above steps.

Although the method for manufacturing the thin film transistor 10 is described above, the method for manufacturing the thin film transistor 10 is not limited thereto.

In the thin film transistor 10 according to the present embodiment, the oxide semiconductor layer 140 includes the Poly-OS film having a novel crystal structure. Although the details are described later, the thin film transistor 10 including the Poly-OS film having such a novel crystal structure has improved electrical characteristics. For example, the field effect mobility of the thin film transistor 10 is improved.

### Third Embodiment

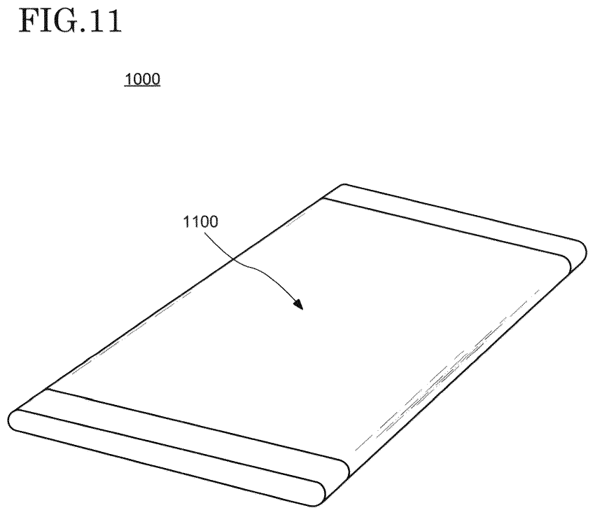

An electronic device according to an embodiment of the present embodiment is described with reference to FIG. 11.

FIG. 11 is a schematic diagram showing an electronic device 1000 according to an embodiment of the present embodiment. Specifically, FIG. 11 shows a smartphone, which is an example of the electronic device 1000. The electronic device 1000 includes a display device 1100 with curved sides. The display device 1100 includes a plurality of pixels for displaying an image. The plurality of pixels are controlled by a pixel circuit, a drive circuit, and the like. The pixel circuit and the drive circuit include the thin film transistor 10 described in the Second Embodiment. Since the thin film transistor 10 has high field effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device, such as a watch, a tablet, a notebook computer, a car navigation system, or a television. The oxide semiconductor film described in the First Embodiment or the thin film transistor 10 described in the First Embodiment can be applied to any electronic device, regardless of whether or not the electronic device has a display device.

### EXAMPLES

The Poly-OS film is described in more detail based on the fabricated samples.

### 1. Fabrication of Samples

In the samples below, an oxide semiconductor film was formed on a substrate by using a sputtering process and an OS annealing process. In the sputtering process, a sputtering target in which indium was contained in a sintered body, and the atomic ratio of indium to all metal elements contained in the sintered body was 70% was used in both the Examples and the Comparative Examples. In any of the samples, the chemical composition of the oxide semiconductor film after the OS annealing process was similar to that of the sputtering target. In the OS annealing process, the reaching temperature was controlled between 350° C. and 450° C. in both the Examples and the Comparative Examples.

### Example 1

A silicon oxide (SiOₓ) film was formed on a glass substrate as a base film. The silicon oxide film was deposited by plasma CVD using monosilane (SiH₄) gas and dinitrogen monoxide (N₂O) gas. The gas flow rate of the monosilane gas was controlled so that the hydrogen concentration in the silicon oxide film was reduced. Specifically, the gas flow rate ratio of the monosilane gas to the dinitrogen monoxide gas in the deposition of the silicon oxide film was SiH₄:N₂O=1:100.

An oxide semiconductor film with a thickness of 30 nm was deposited on the base film by the sputtering process. Then, the OS annealing process was performed on the deposited oxide semiconductor film in an air atmosphere.

### Example 2

A stacked film in which an aluminum oxide film was deposited on a silicon oxide film was formed on a glass substrate as a base film. The silicon oxide film was deposited by plasma CVD using monosilane (SiH₄) gas and dinitrogen monoxide (N₂O) gas. The gas flow rate of the monosilane gas was controlled so that the hydrogen concentration in the silicon oxide film was reduced. Specifically, the gas flow rate ratio of the monosilane gas to the dinitrogen monoxide gas in the deposition of the silicon oxide film was SiH₄:N₂O=1:100.

The aluminum oxide film was deposited by a sputtering method using an aluminum (Al) target.

An oxide semiconductor film with a thickness of 30 nm was deposited on the base film by the sputtering process. Then, the OS annealing process was performed on the deposited oxide semiconductor film in an air atmosphere.

### [Example 3-1], [Example 3-2]

A stacked film in which an aluminum oxide film was deposited on a silicon oxide film was formed on a glass substrate as a base film. The silicon oxide film was deposited by plasma CVD using monosilane (SiH₄) gas and dinitrogen monoxide (N₂O) gas. The gas flow rate of the monosilane gas was controlled so that the hydrogen concentration in the silicon oxide film was reduced. Specifically, the gas flow rate ratio of the monosilane gas to the dinitrogen monoxide gas in the deposition of the silicon oxide film was SiH₄:N₂O=1:100. The aluminum oxide film was deposited by a sputtering method using an aluminum (Al) target.

An oxide semiconductor film with a thickness of 30 nm was deposited on the base film by the sputtering process. Then, the OS annealing process was performed on the deposited oxide semiconductor film in an air atmosphere.

### Comparative Example 1

A silicon oxide (SiOₓ) film was formed on a glass substrate as a base film. The silicon oxide film was deposited by plasma CVD using monosilane (SiH₄) gas and dinitrogen monoxide (N₂O) gas. The gas flow rate of the monosilane gas was controlled under a conventional condition. Specifically, the gas flow rate ratio of the monosilane gas to the dinitrogen monoxide gas in the deposition of the silicon oxide film was SiH₄:N₂O=1:30.

An oxide semiconductor film with a thickness of 30 nm was deposited on the base film by the sputtering process. Then, the OS annealing process was performed on the deposited oxide semiconductor film in an air atmosphere.

### Comparative Example 2

A stacked film in which an aluminum oxide film was deposited on a silicon oxide film was formed on a glass substrate as a base film. The silicon oxide film was deposited by plasma CVD using monosilane (SiH₄) gas and dinitrogen monoxide (N₂O) gas. The gas flow rate of the monosilane gas was controlled under a conventional condition. Specifically, the gas flow rate ratio of the monosilane gas to the dinitrogen monoxide gas in the deposition of the silicon oxide film was SiH₄:N₂O=1:30. The aluminum oxide film was deposited by a sputtering method using an aluminum (Al) target.

An oxide semiconductor film with a thickness of 30 nm was deposited on the base film by the sputtering process. Then, the OS annealing process was performed on the deposited oxide semiconductor film in an air atmosphere.

The differences in each fabricated sample are summarized in Table 1.

TABLE 1

| | | Gas Flow | Thickness of |
|---|---|---|---|
| Sample | | Ratio | Oxide Semiconductor |
| Name | Base Film | SiH₄:N₂O | Film |
| Example 1 | SiO | 1:100 | 30 nm |
| Example 2 | AlOₓ/SiOₓ | 1:100 | 30 nm |
| Example 3-1 | AlOₓ/SiOₓ | 1:100 | 15 nm |
| Example 3-2 | AlOₓ/SiOₓ | 1:100 | 15 nm |
| Comparative | SiOₓ | 1:30 | 30 nm |
| Example 1 | | | |
| Comparative | AlOₓ/SiOₓ | 1:30 | 30 nm |
| Example 2 | | | |

### 2. Crystal Structure Analysis by XRD Method

The crystal structure of the oxide semiconductor film of each fabricated sample was analyzed by an XRD method. The crystal structure analysis by the XRD method was performed using a SmartLab device (manufactured by Rigaku Corporation) under the conditions shown in Table 2.

TABLE 2

| X-ray Source | Cu-Kα | |
|---|---|---|
| Tube Voltage | 40 | kV |
| Tube Current | 200 | mA |
| Optical System | Parallel Beam Method | |
| Slit Configuration | Solar slit 5 degrees, | |
| | Entrance slit 1 mm, | |
| | Receiving slit 1 mm | |
| Scanning Range | 20 to 70 | degrees |
| (2θ measurement: | | |
| (out-of-plane)) | | |
| Measurement Width | 0.0052 | degrees |
| Scanning Speed | 2 | degrees/min |

The peaks were smoothed by an analysis program (JADE 6) in order to confirm the existence of a crystal structure from the measurement results, and then the identification of the crystalline phase was performed using the crystal structure file of bixbyite-type structure 14388 of ICSD (Inorganic Crystal Structure Database: Association for Chemical Information). After the identification of the crystalline phase, broad patterns that were not indexed were determined to be background noise from the substrate and were removed by three-dimensional approximation.

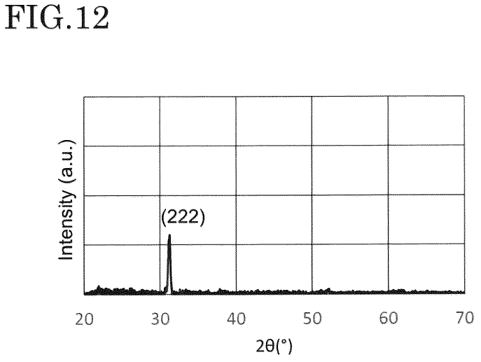

FIGS. 12 to 17 show XRD diffraction patterns of the Examples 1 to 3-2 and the Comparative Examples 1 and 2, respectively. All of the oxide semiconductor films have a peak at a diffraction angle (2θ) near 31 degrees. The diffraction angle near 31 degrees is attributed to the (222) plane of a bixbyite structure, and it is confirmed that all of the oxide semiconductor films have a bixbyite crystal structure.

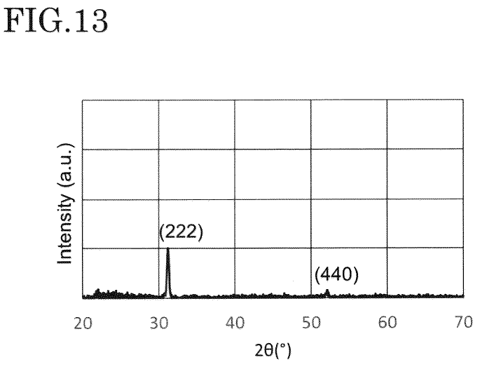

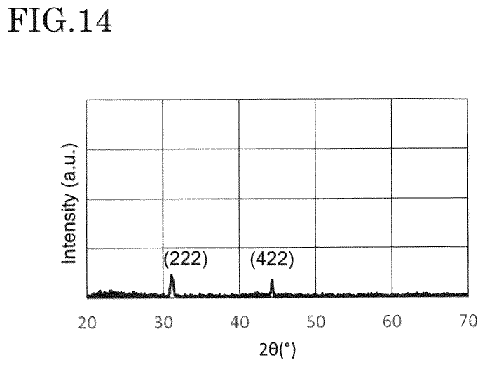

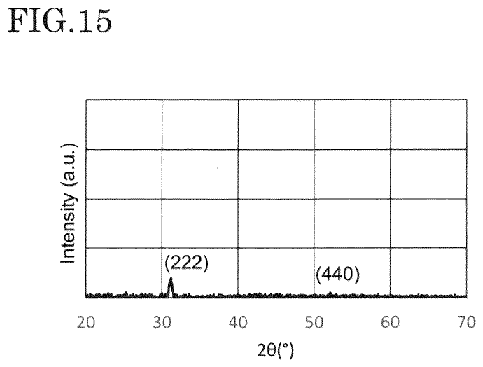

As shown in FIG. 12, no clear peak other than at a diffraction angle near 31 degrees is observed in the oxide semiconductor film of the Example 1. As shown in FIG. 13, peaks are observed at a diffraction angle near 52 degrees in addition to the diffraction angle near 31 degrees in the oxide semiconductor film of the Example 2. The diffraction angle near 52 degrees is attributed to the (440) plane of the bixbyite structure. As shown in FIG. 14, peaks are observed at a diffraction angle near 44 degrees in addition to the diffraction angle near 31 degrees in the oxide semiconductor film of the Example 3-1. The diffraction angle near 44 degrees is attributed to the (422) plane of the bixbyite structure. As shown in FIG. 15, peaks are observed at the diffraction angle near 52 degrees in addition to the diffraction angle near 31 degrees in the oxide semiconductor film of Example 3-2.

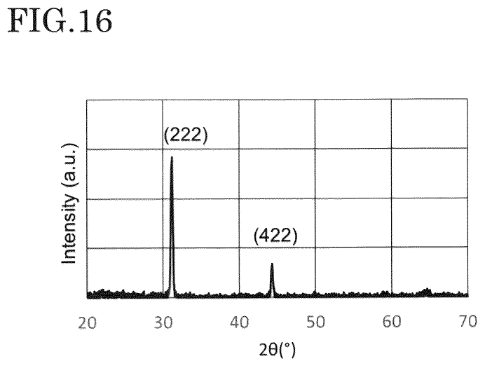

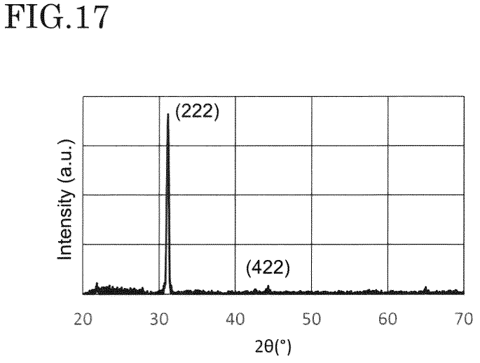

As shown in FIG. 16, peaks are observed at the diffraction angle near 44 degrees in addition to the diffraction angle near 31 degrees in the oxide semiconductor film of the Comparative Example 1. As shown in FIG. 17, peaks are observed at the diffraction angle near 44 degrees in addition to the diffraction angle of about 31 degrees also in the oxide semiconductor film of the Comparative Example 2.

The results of the XRD diffraction patterns in FIGS. 12 to 17 are summarized in Table 3. Table 3 shows the peak intensity of the (222) plane relative to the peak intensity of the (422) plane as the peak intensity ratio. Further, Table 3 also shows the crystallite diameter calculated from the XRD diffraction pattern. The crystallite diameter was calculated based on the half-width of the peak at the diffraction angle near 31.2 degrees (corresponding to the (222) plane) that was confirmed in each oxide semiconductor film.

TABLE 3

| | Peak Intensity | | | Peak | |
|---|---|---|---|---|---|
| Sample | (222) | (422) | (440) | Intensity | Crystallite |
| Name | plane | plane | plane | Ratio | Size |
| Example 1 | 298 | — | — | — | 24.8 nm |
| Example 2 | 251 | — | 39 | — | 24.5 nm |
| Example 3-1 | 114 | 90 | — | 1.3 | 17.4 nm |
| Example 3-2 | 98 | — | 25 | — | 17.7 nm |
| Comparative | 707 | 171 | — | 4.1 | 26.6 nm |
| Example 1 | | | | | |
| Comparative | 909 | 42 | — | 21.6 | 28.4 nm |
| Example 2 | | | | | |

As can be seen from Table 3, the oxide semiconductor films of the Examples 1 to 3-2 have smaller peak intensities of the (222) plane than the oxide semiconductors of the Comparative Examples 1 and 2. Although the Example 1 and the Comparative Example 1 differ only in the gas flow rate of monosilane gas in the film deposition conditions for the silicon oxide film, which is the base film, the peak intensity of the (222) plane of the Example 1 is less than half the peak intensity of the (222) plane of the Comparative Example 1. Similarly, although the Example 2 and the Comparative Example 2 differ only in the gas flow rate of monosilane gas in the film deposition conditions for the silicon oxide film, which is the base film, the peak intensity of the (222) plane of the Example 2 is less than half the peak intensity of the (222) plane of the Comparative Example 2.

Further, although the peak of the (422) plane is observed in the Comparative Examples 1 and 2, the peak of the (422) plane is not observed in the Examples 1, 2, and 3-2. The peak of the (422) plane is observed in the Example 3-1. However, the peak intensity ratio in the Example 3-1 is smaller than that in the Comparative Examples 1 and 2. While the peak intensity ratios of the Comparative Examples 1 and 2 are each greater than 3.0, the peak intensity ratio of the Example 3-1 is less than or equal to 3.0.

In Examples 1 and 2 in which the thickness of the oxide semiconductor film is 30 nm, the crystallite diameter is greater than or equal to 20 nm. In Examples 3-1 and 3-2 in which the thickness of the oxide semiconductor film is 15 nm, the crystallite diameter is 1.2 times the thickness of the oxide semiconductor film. That is, the crystallite diameter of the oxide semiconductor film in the Examples 3-1 and 3-2 is 0.95 times greater than or equal to the thickness of the oxide semiconductor film, and is almost the same as the thickness of the oxide semiconductor film.

### 3. Electrical Characteristics

Thin film transistors including the oxide semiconductor films of the above-described Examples and Comparative Examples were fabricated using the manufacturing method described in the Second Embodiment, and their electrical characteristics were measured. Table 4 shows the field effect mobility calculated from the electrical characteristics.

TABLE 4

| Sample | Field Effect |
|---|---|
| Name | Mobility |
| Example 1 | 33.0 cm²/Vs |
| Example 2 | 58.6 cm²/Vs |
| Example 3-1 | 39.1 cm²/Vs |
| Example 3-2 | 41.3 cm²/Vs |
| Comparative | 20.7 cm²/Vs |
| Example 1 | |
| Comparative | 33.5 cm²/Vs |
| Example 2 | |

As shown in Table 4, a field effect mobility greater than 30 cm²/Vs is obtained in the thin film transistors of all the Examples. Further, although the only difference between the Example 1 and the Comparative Example 1 is the gas flow rate of monosilane gas in the film deposition conditions for the silicon oxide film, which is the base film, the field effect mobility of the thin film transistor of the Example 1 is greater than that of the thin film transistor of the Comparative Example 1. Similarly, although the only difference between the Example 2 and the Comparative Example 2 is the gas flow rate of monosilane gas in the film deposition conditions for the silicon oxide film, which is the base film, the field effect mobility of the thin film transistor of the Example 2 is greater than that of the thin film transistor of the Comparative Example 2.

As can be seen from this result, when the Poly-OS film is used for the channel of a thin film transistor, the field effect mobility is not reduced but is rather improved.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. An oxide semiconductor film having a polycrystalline structure,
wherein a crystal structure of the oxide semiconductor film is a bixbyite structure, and
wherein in the oxide semiconductor film, no peak intensity of a (422) plane is observed in an out-of-plane XRD diffraction pattern using Cu-Kα radiation.

2. The oxide semiconductor film according to claim 1, wherein a crystallite diameter calculated from a peak of a (222) plane in the XRD diffraction pattern is greater than or equal to 15 nm.

3 The oxide semiconductor film according to claim 1,
wherein the oxide semiconductor film contains indium and at least one or more metal elements, and
wherein a ratio of the indium to the indium and the at least one or more metal elements is greater than or equal to 50%.

4. The oxide semiconductor film according to claim 1,
wherein the oxide semiconductor film is provided in contact with an oxide insulating film, and
wherein the oxide insulating film contains one or more metal elements selected from aluminum, magnesium, calcium, scandium, gallium, germanium, strontium, nickel, tantalum, yttrium, zirconium, barium, hafnium, cobalt, and lanthanoid elements.

5. The oxide semiconductor film according to claim 1, wherein the oxide insulating film comprises aluminum oxide.

6. A thin film transistor, comprising:
the oxide semiconductor film according to claim 1;
a gate electrode provided over the oxide semiconductor film; and
a gate insulating film provided between the oxide semiconductor film and the gate electrode.

7. An electronic device comprising the thin film transistor according to claim 6.
